(19) United States
(12) Patent Application Publication
(10) Pub. No.: US 2019/0327829 A1
(43) Pub. Date: Oct. 24, 2019

(54) STRETCHABLE BOARD

(71) Applicant: FUJIKURA LTD., Tokyo (JP)

(72) Inventors: Shingo OGURA, Chiba (JP); Tatsuo SUEMASU, Chiba (JP); Hiroyuki HIRANO, Chiba (JP); Masaaki ISHI, Chiba (JP)

(73) Assignee: Fujikura Ltd., Tokyo (JP)

(21) Appl. No.: 16/310,659

(22) PCT Filed: Feb. 6, 2017
(86) PCT No.: PCT/JP2017/004183

§ 371 Date: Dec. 17, 2018

(30) Foreign Application Priority Data
Jul. 12, 2016 (JP) 2016-137323

(51) Int. Cl. H05K 1/02; H05K 1/09; H05K 3/20; H05K 1/03

(52) U.S. Cl. CPC H05K 1/0283; H05K 1/09; H05K 3/20; H05K 1/189; H05K 2201/0133; H05K 2201/0314; H05K 2201/0162; H05K 1/0393

(57) ABSTRACT

A stretchable board includes: a substrate having a stretching property; and a conductor portion provided on the substrate, wherein the conductor portion comprises: conductor wires intersecting with each other; and an opening surrounded by the conductor wires.

### CROSS-REFERENCE TO RELATED APPLICATION

For designated countries that are permitted to be incorporated by reference in the literature, the contents of Patent Application No. 2016-137323, filed with Japan Patent Office on Jul. 12, 2016 are incorporated herein by reference and is regarded as a part of the description of this specification.

### TECHNICAL FIELD

The present invention relates to a stretchable board.

### BACKGROUND ART

A circuit board in which a wiring wire has a corrugated zigzag pattern shape and which is stretchable in terms of shape has been known as a stretchable flexible circuit board (for example, see Patent Document 1).

### CITATION LIST

### Patent Document

Patent Document 1: JP 2013-187380 A

In the above-described stretchable board, it is difficult to sufficiently suppress an increase in electric resistance value of the board due to stretching. For this reason, durability of the stretchable board with respect to stretching may be inferior.

### SUMMARY

One or more embodiments of the invention provide a stretchable board capable of improving durability with respect to stretching.

[1] A stretchable board according to the invention includes a substrate having a stretching property, and a conductor portion provided on the substrate, in which the conductor portion includes conductor wires intersecting with each other, and an opening formed by the conductor wires in plan view.

[2] In the invention, a first imaginary straight line extending in a direction orthogonal to an extending direction of the conductor portion may intersect with at least two conductor wires in plan view.

[3] In the invention, the conductor portion may include the openings mutually having the same shape, and the openings may be repeatedly arranged along the extending direction of the conductor portion.

[4] In the invention, at least one of Expression (1) or Expression (2) below may be satisfied, and Expression (3) below may be satisfied:

W₁≤100 μm (1)

W₁/W₂≤0.1 (2)

2≤P₁/W₁≤10 (3)

Where, in the above Expressions (1) to (3), W₁ denotes a width of the conductor wire, W₂ denotes a width of the conductor portion, and P₁ denotes a pitch between adjacent conductor wires.

[5] In the invention, Expression (4) below may be satisfied:

0.2≤H/W₁≤4 (4)

where H denotes a height of the conductor wire in the above Expression (4).

[6] In the invention, the conductor wire may extend to be inclined with respect to the extending direction of the conductor portion.

[7] In the invention, Expression (5) below may be satisfied:

30°≤θ₁<90° (5)

where θ₁ denotes an angle between a second imaginary straight line along the extending direction of the conductor portion and a third imaginary straight line along an extending direction of the conductor wires in the above Expression (5).

[8] In the invention, Expression (6) below may be satisfied:

45°≤θ₁≤75° (6).

[9] In the invention, the conductor wire may contain a conductive material having a stretching property, and the conductive material may include a conductive particle and an elastomer.

[10] In the invention, the conductor wire may have a first surface facing the substrate, a second surface on an opposite side from the first surface, and a third surface interposed between the first surface and the second surface, a surface roughness of the first surface may be relatively larger than a surface roughness of the second surface, and the surface roughness of the first surface may be relatively larger than a surface roughness of the third surface.

[11] In the invention, the substrate may include a linear main surface in section view, and Expression (7) below may be satisfied:

90°≤θ₂≤120° (7)

where θ₂ denotes an angle between a fourth imaginary straight line along the main surface and a fifth imaginary straight line along the third surface in the above Expression (7).

According to one or more embodiments of the invention, an opening formed by a plurality of conductor wires is deformable by stretching. Accordingly, it is possible to improve durability of a stretchable board with respect to stretching.

### BRIEF DESCRIPTION OF DRAWINGS

FIG. 1 is a perspective view illustrating a stretchable board for connecting external circuits to each other according to one or more embodiments of the invention;

FIG. 2 is a plan view illustrating the stretchable board according to one or more embodiments of the invention;

FIG. 3 is a partial enlarged view of a portion III of FIG. 2;

FIG. 4 is a plan view illustrating a first modification of the stretchable board according to one or more embodiments of the invention;

FIG. 5 is a plan view illustrating a second modification of the stretchable board according to one or more embodiments of the invention;

FIG. 6 is a cross-sectional view taken along VI-VI line of FIG. 3;

FIG. 7A to FIG. 7E are cross-sectional views illustrating a method of manufacturing the stretchable board according to one or more embodiments of the invention;

FIG. 8 is a plan view for description of an operation of the stretchable board according to one or more embodiments of the invention; and

FIG. 9 is a cross-sectional view illustrating a stretchable board according to one or more embodiments of the invention.

### DETAILED DESCRIPTION OF EMBODIMENTS

Hereinafter, embodiments of the invention will be described with reference to drawings.

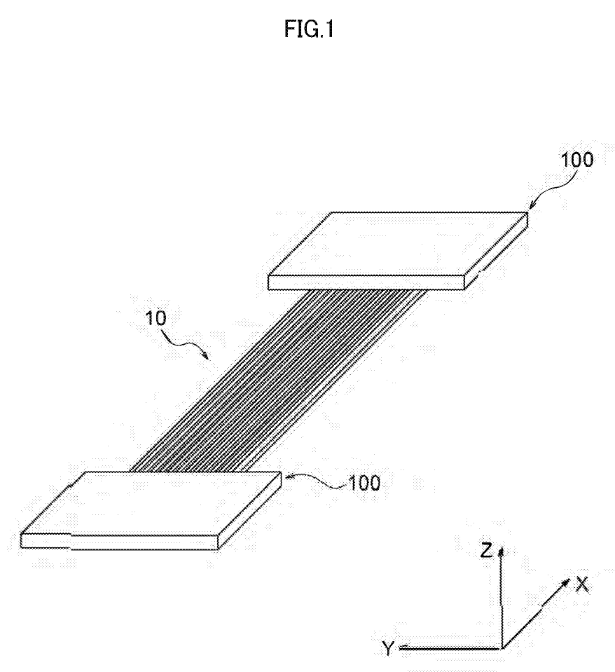

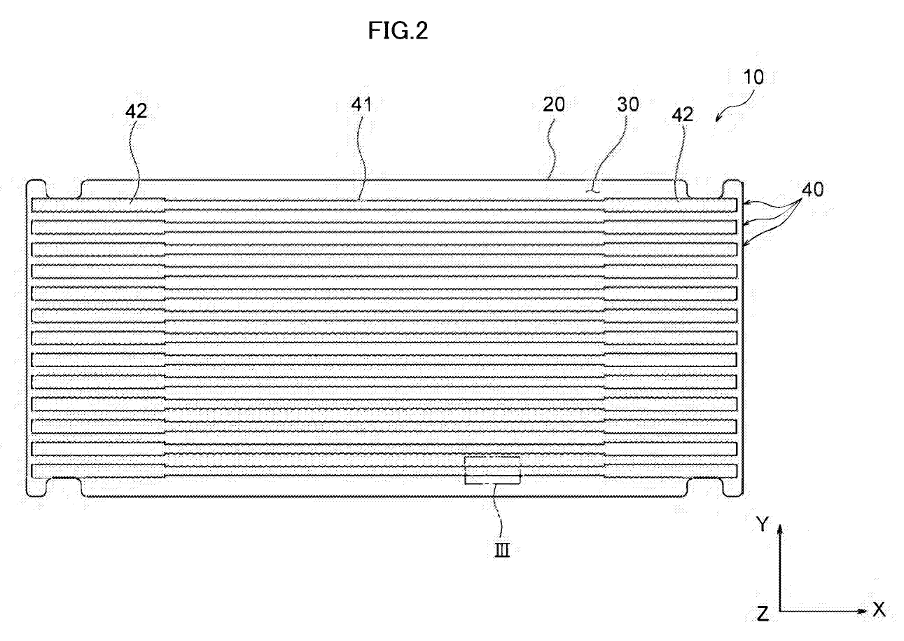

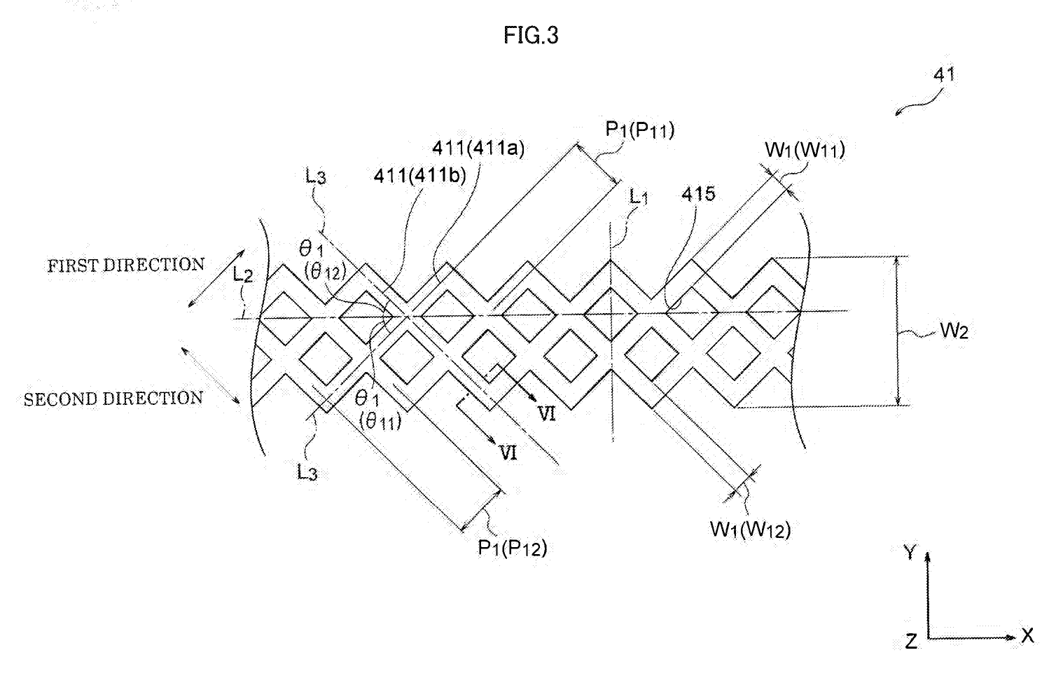

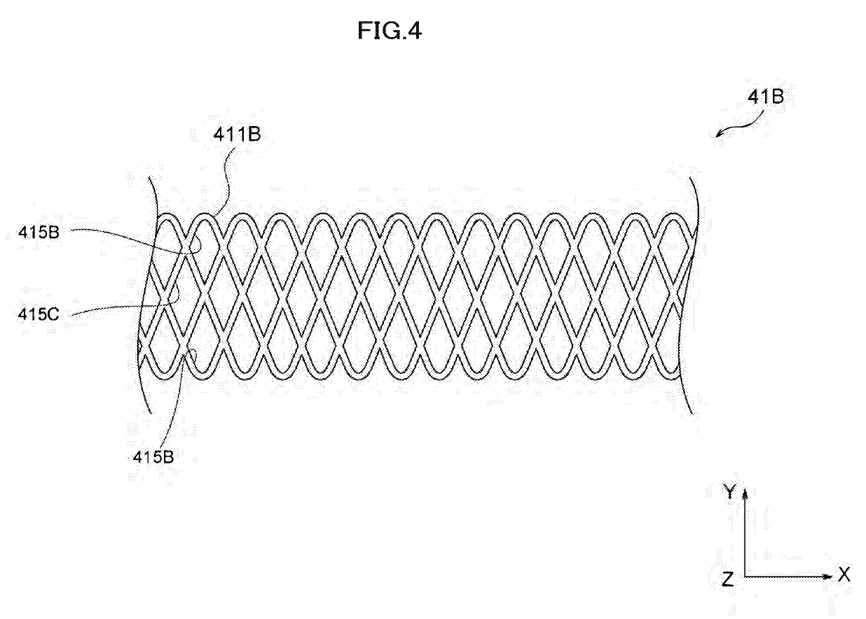

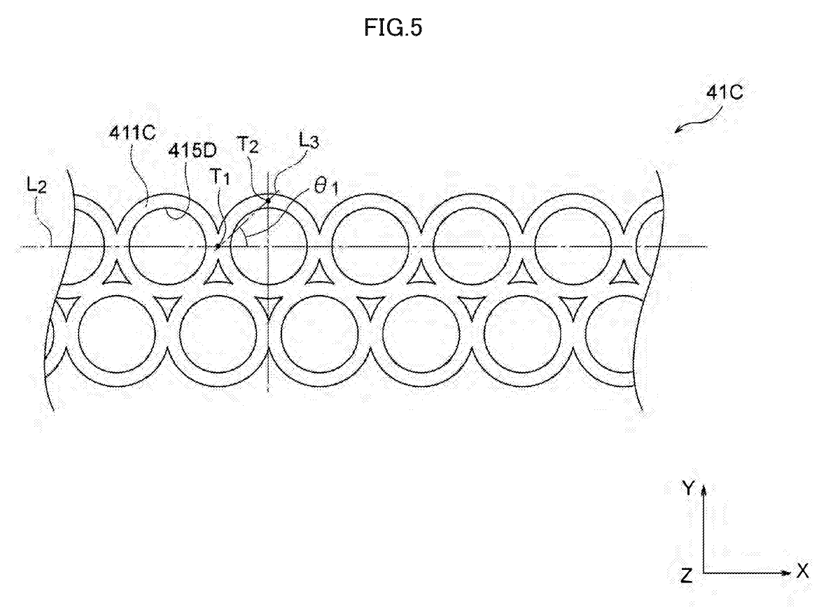

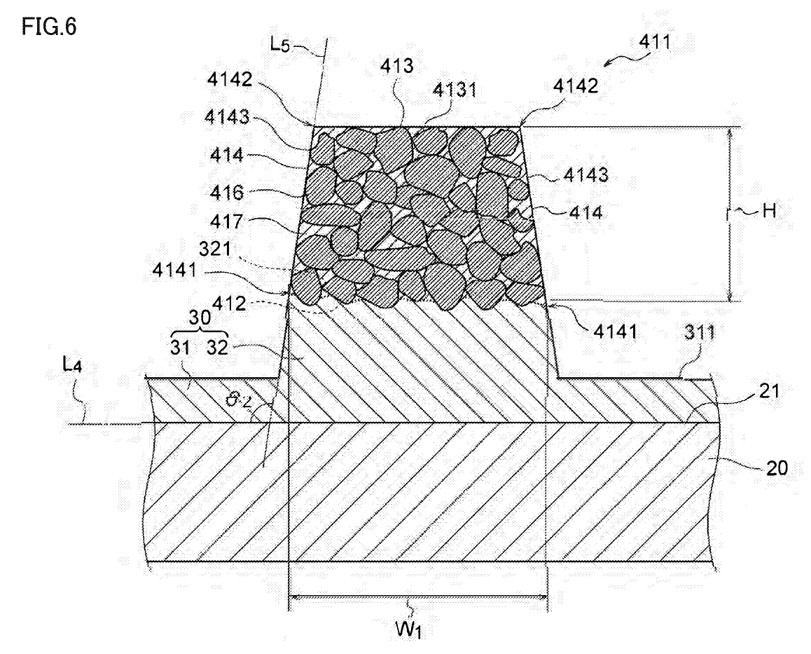

FIG. 1 is a perspective view illustrating a stretchable board for connecting external circuits to each other according to one or more embodiments of the invention, FIG. 2 is a plan view illustrating the stretchable board according to one or more embodiments of the invention, FIG. 3 is a partial enlarged view of a portion III of FIG. 2, FIG. 4 is a plan view illustrating a first modification of the stretchable board according to one or more embodiments of the invention, FIG. 5 is a plan view illustrating a second modification of the stretchable board according to one or more embodiments of the invention, and FIG. 6 is a cross-sectional view taken along VI-VI line of FIG. 3.

As illustrated in FIG. 1, for example, a stretchable board 10 according to one or more embodiments of the invention is a wiring board that electrically connects external circuits 100 such as a rigid board and a flexible printed circuit board (FPC) to each other. Although such a stretchable board 10 is not particularly limited, for example, the stretchable board 10 is particularly applied to a portion requiring expansion and contraction such as a movable portion/a bent portion of an industrial robot.

As illustrated in FIG. 2, FIG. 3, and FIG. 6, the stretchable board 10 includes a substrate 20, an adhesive portion 30 provided on the substrate 20, and a conductor portion 40 provided on the adhesive portion 30.

The substrate 20 is a plate-shaped member formed in a rectangular shape. A main surface 21 of the substrate 20 (the main surface 21 on an opposite side from a main surface in contact with the substrate 20 among main surfaces of the substrate 20) is a substantially flat surface formed in a linear shape in section view. The substrate 20 is made of a material having elasticity. Young's modulus of the material included in the substrate 20 is 0.1 MPa to 100 MPa. As such a substrate 20, it is possible to use an elastic sheet obtained by shaping natural rubber, styrene butadiene rubber, butadiene rubber, chloroprene rubber, butyl rubber, nitrile rubber, ethylene propylene rubber, acrylic rubber, urethane rubber, silicone rubber, fluororubber, etc. into a sheet or a material obtained by shaping a resin material such as nylon, polyester, acrylic, or polyamide into a fiber or a woven fabric.

From a viewpoint of improving a stretching property of the stretchable board 10, a thickness of the substrate 20 is set to be relatively small. Even though depending on a position to which the stretchable board 10 is applied, in one or more embodiments, the thickness of the substrate 20 is less than 1 mm, less than 0.3 mm, or less than 0.1 mm.

The adhesive portion 30 is provided directly on the substrate 20. The adhesive portion 30 bonds the substrate 20 and the conductor portion 40 to each other. In addition, the adhesive portion 30 integrally holds the conductor portion 40 so that the conductor portion 40 is not separated.

As illustrated in FIG. 6, the adhesive portion 30 of one or more embodiments of the invention includes a flat portion 31 and a protruding portion 32. The flat portion 31 is a portion of the adhesive portion 30 formed in the shape of a layer. An upper surface 311 of the flat portion 31 is a substantially flat surface having a linear shape in section view. A thickness of the flat portion 31 is 5 μm to 100 μm.

The protruding portion 32 is integrally formed with the flat portion 31. This protruding portion 32 is provided to correspond to the conductor portion 40. The protruding portion 32 protrudes from the flat portion 31 in a direction away from the substrate 20.

An adhesive portion contact surface 321 of the protruding portion 32 in contact with the conductor portion 40 has an uneven shape which is complementary to an uneven shape of the conductor portion 40 in the case of viewing a cross section along a width direction of a conductor wire 411 (described below) of the conductor portion 40. In addition, also in the case of viewing a cross section along an extending direction of the conductor wire 411, this adhesive portion contact surface 321 has an uneven shape which is complementary to an uneven shape of the conductor portion 40. Note that, in order to describe the stretchable board 10 of one or more embodiments of the invention so that the description is easy to understand, uneven shapes of the adhesive portion contact surface 321 and a conductor portion contact surface 412 are exaggerated in FIG. 6.

As such an adhesive portion 30, it is possible to use an elastic sheet obtained by shaping natural rubber, styrene butadiene rubber, butadiene rubber, chloroprene rubber, butyl rubber, nitrile rubber, ethylene propylene rubber, acrylic rubber, urethane rubber, silicone rubber, fluororubber, etc. into a sheet or a resin material such as nylon, polyester, acrylic, or polyamide.

The conductor portion 40 is provided directly on the adhesive portion 30. In one or more embodiments of the invention, as illustrated in FIG. 2, thirteen conductor portions 40 extend along an X direction of the figure and are arranged in parallel in a Y direction of the figure. As long as adjacent conductor portions 40 are electrically insulated from each other, a pitch between the adjacent conductor portions 40 is not particularly limited.

As illustrated in FIG. 2, each of the conductor portions 40 includes a wiring portion 41 and a terminal portion 42. The wiring portion 41 and the terminal portion 42 are integrally formed. The term “integrally” means that members are not separated from each other and are formed as an integral structure by the same material (conductive particles having the same particle diameter, elastomer, etc.).

Rectangular terminal portions 42 are provided at both ends of each wiring portion 41 in a longitudinal direction. The terminal portions 42 are electrically connected to the external circuits 100, respectively. Note that, various shapes may be adopted as a shape of the terminal portion 42 according to a connection structure with the external circuit 100.

As illustrated in FIG. 3, the wiring portion 41 includes a plurality of conductor wires 411. The plurality of conductor wires 411 is arranged to cross each other. In this way, the wiring portion 41 is formed in a mesh shape.

More specifically, a conductor wire 411a linearly extends along a direction inclined by +45° with respect to the X direction (hereinafter also simply referred to as “first direction”), and a plurality of conductor wires 411a are arranged at an equal pitch P₁₁ in a direction substantially perpendicular to the first direction (hereinafter also simply referred to as “second direction”). Meanwhile, a conductor wire 411b linearly extends along the second direction, and a plurality of conductor wires 411b are arranged at an equal pitch P₁₂ in the first direction. Further, since these conductor wires 411a and 411b are orthogonal to each other, the mesh-shaped wiring portion 41 is formed. Note that, in this specification, a pitch refers to a center-to-center distance. The conductor wire 411 collectively refers to the above-described conductor wires 411a and 411b.

In one or more embodiments of the invention, a first imaginary straight line L₁ extending in a width direction of the wiring portion 41 (a direction orthogonal to an extending direction of the wiring portion 41) intersects with at least two conductor wires 411 in plan view. For example, even when the first imaginary straight line L₁ is extended on intersection points of the plurality of conductor wires 411, the first imaginary straight line L₁ intersects with two conductor wires 411 (that is, the first imaginary straight line L₁ intersects with intersection points of two or more conductor wires 411).

Further, in one or more embodiments of the invention, the conductor wire 411 extends to be inclined with respect to the extending direction of the wiring portion 41. More specifically, a third imaginary straight line L₃ along the extending direction of the conductor wire 411 extends to be inclined with respect to a second imaginary straight line L₂ along the extending direction of the wiring portion 41. For this reason, As compared with a case in which the conductor wire is extended in a direction parallel or perpendicular to the extending direction of the wiring portion, it is possible to attempt a reduction of an electric resistance value in the conductor portion 40 while attempting improvement of the stretching property of the stretchable board 10.

In one or more embodiments, an angle θ₁ between the second imaginary straight line L₂ along the extending direction of the wiring portion 41 and the third imaginary straight line L₃ along the extending direction of the conductor wire 411 is set to satisfy Expression (8) below, or set to satisfy Expression (9) below. Note that, the angle θ₁ is an angle that collectively refers to an angle θ11 between the second imaginary straight line L₂ and the third imaginary straight line L₃ along an extending direction of the conductor wire 411a and an angle θ₁₂ between the second imaginary straight line L₂ and the third imaginary straight line L₃ along an extending direction of the conductor wire 411b.

30°≤θ₁<90° (8)

45°≤θ₁≤75° (9)

Note that, when the conductor wire 411 is extended in a direction inclined by 45° with respect to the extending direction of the wiring portion 41 as in one or more embodiments of the invention, the stretching property of the stretchable board 10 is hardly impaired not only in a case in which the stretchable board 10 is stretched along the extending direction (X direction) of the wiring portion 41 but also in a case in which the stretchable board 10 is stretched along the width direction (Y direction) of the wiring portion 41.

In addition, a width W₁ of the conductor wire 411 is set to satisfy Expression (10) below. Note that, the width W₁ is a width that collectively refers to a width W₁₁ of the conductor wire 411a and a width W₁₂ of the conductor wire 411b.

W₁≤100 μm (10)

In addition, in one or more embodiments, a relationship between the width W₁ of the conductor wire 411 and a width W₂ of the wiring portion 41 is set to satisfy Expression (11) below, or set to satisfy Expression (12) below. Note that, in one or more embodiments of the invention, in a case in which side ends of the wiring portion 41 are closed by the conductor wire 411, the width W₂ of the wiring portion 41 is a distance between intersection points of conductor wires 411 present at side ends on both sides of the wiring portion 41 (see FIG. 3). Although not illustrated, in a case in which the side ends of the wiring portion are not closed by the conductor wire, the width of the wiring portion is a distance between distal ends of the conductor wire protruding outward from intersection points of conductor wires present at outermost sides of the wiring portion.

W₁/W₂≤0.1 (11)

0.01≤W₁/W₂≤0.1 (12)

The wiring portion 41 of one or more embodiments of the invention is set such that at least one of the above Expressions (10) and (11) is satisfied and a relationship between the width W₁ of the conductor wire 411 and a pitch P₁ between adjacent conductor wires 411 satisfies Expression (13) below. Note that, the pitch P₁ is a pitch that collectively refers to the pitch P₁₁ between adjacent conductor wires 411a and the pitch P₁₂ between adjacent conductor wires 411b.

2≤P₁/W₁≤10 (13)

Note that, in one or more embodiments, a ratio (P₁/W₁) of the pitch P₁ to the width W₁ is 5 to 10 (5≤P₁/W₁≤10), or is approximately 5 (P₁/W₁≈5).

Note that, a configuration of the wiring portion 41 is not particularly limited to the above description. For example, although the pitch P₁₁ between the conductor wires 411a is substantially the same as the pitch P₁₂ between the conductor wires 411b (P₁₁=P₁₂) in one or more embodiments of the invention, it is not particularly limited thereto. The pitch P₁₁ between the conductor wires 411a may be different from the pitch P₁₂ between the conductor wires 411b (P₁₁≠P₁₂). Although the width W₁₁ of the conductor wire 411a is substantially the same as the width W₁₂ of the conductor wire 411b (W₁₁=W₁₂) in one or more embodiments of the invention, it is not particularly limited thereto. The width W₁₁ of the conductor wire 411a may be different from the width W₁₂ of the conductor wire 411b (W₁₁≠W₁₂).

The wiring portion 41 includes an opening 415 formed by causing a plurality of linear conductor wires 411 to intersect with each other. In one or more embodiments of the invention, a plurality of rectangular (rhomboid) openings 415 is formed by the plurality of conductor wires 411 being orthogonal to each other. In one or more embodiments of the invention, as the openings 415 are deformed in response to stretching of the stretchable board 10, the wiring portion 41 can follow stretching of the stretchable board 10.

The plurality of openings 415 mutually have the same shape. The plurality of openings 415 mutually having the same shape is repeatedly arranged along the extending direction (X direction) of the wiring portion 41. In one or more embodiments of the invention, the plurality of openings 415 repeatedly arranged in the extending direction of the wiring portion 41 is arranged in parallel in two rows in the width direction (Y direction) of the wiring portion 41. All the plurality of openings 415 aligned in the two rows have the same shape, and all the openings 415 included in the wiring portion 41 have the same shape. Note that, the plurality of openings 415 mutually having the same shape may be arranged in parallel in three or more rows.

Note that, the shape of the opening 415 is not particularly limited to the above description. For example, it is possible to adopt a triangle such as an equilateral triangle, an isosceles triangle or a right triangle, or a quadrangle such as a parallelogram or a trapezoid. Alternatively, the shape of the opening 415 may be an n-polygon such as a hexagon, an octagon, a dodecagon or a decagon, a circle, an ellipse, or a star. In this way, a geometric pattern obtained by repeating various graphic units can be used as the shape of the opening 415.

Note that, the conductor wire 411 of one or more embodiments of the invention has a linear shape. However, it is not particularly limited thereto, and it is possible to adopt a curved shape, a horseshoe shape, or a zigzag line shape. For example, in FIG. 4, the conductor wire 411B has a shape like a sinusoidal curve. In this case, a wiring portion 41B includes: a plurality of openings 415B formed at both side ends of the wiring portion 41B by the plurality of curved conductor wires 411B intersecting with each other and formed by a curved part and a linear part of the conductor wire 411B; and a plurality of openings 415C formed substantially at a center of the wiring portion 41B and formed in the shape of a rhomboid.

In one or more embodiments of the invention illustrated in FIG. 4, the plurality of openings 415B mutually having the same shape is repeatedly arranged along an extending direction of the wiring portion 41B. In addition, the plurality of openings 415C mutually having the same shape is also repeatedly arranged along the extending direction of the wiring portion 41B. In this case, it is possible to suppress stress concentration on an outermost side of the wiring portion 41B by giving a curvature to an inflection point of the conductor wire 411B on the outermost side of the wiring portion 41B.

In addition, as in one or more embodiments of the invention illustrated in FIG. 5, in a wiring portion 41C, in plan view, a plurality of substantially circular openings 415D formed by a plurality of conductor wires 411C and mutually having the same shape may be repeatedly arranged along an extending direction of the wiring portion 41C. In one or more embodiments, an angle θ₁ satisfies the above Expression (8), or satisfies the above Expression (9). Note that, in one or more embodiments of the invention, a third imaginary straight line L₃ is set to an imaginary straight line passing through an intersection point T₁ and an intersection point T₂. The intersection point T₁ is an intersection point of a contour of an opening 415D and an imaginary straight line which passes through a center of the opening 415D and extends along the extending direction of the wiring portion 41C. The intersection point T₂ is an intersection point of a contour of an opening 415D and an imaginary straight line which passes through a center of the opening 415D and extends along a direction orthogonal to the extending direction of the wiring portion 41C.

Next, the conductor wire 411 of one or more embodiments of the invention will be described in more detail.

As illustrated in FIG. 6, the conductor wire 411 of one or more embodiments of the invention is made of a conductive material having a stretching property, and includes a conductive particle 416 and an elastomer 417. The conductive particle 416 is dispersed in the elastomer 417, and the elastomer 417 functions as a binder.

As such a conductive particle 416, it is possible to use a metal material made of a metal such as gold, silver, platinum, ruthenium, lead, tin, zinc or bismuth, an alloy thereof, or a nonmetallic material such as carbon. A shape of the conductive particle 416 corresponds to a scaly or indefinite shape.

As the elastomer 417, it is possible to use acrylic rubber, urethane rubber, nitrile rubber, silicone rubber, fluororubber, etc. Note that, in the conductor wire 411, a ratio of a weight of the conductive particle 416 to a total weight of the conductor wire 411 is set to 75% to 95%.

Note that, in addition to the above-described materials, the conductor wire 411 may further contain an additive such as an antioxidant, a flame retardant, or a softener.

A thickness H of the conductor wire 411 is 5 μm to 400 μm. Further, from a viewpoint of facilitating formation of the conductor wire 411 while ensuring conductivity, a ratio (aspect ratio) of the thickness H to a width W₁ of the conductor wire 411 is set to satisfy Expression (14) below.

0.2≤H/W₁≤4 (14)

The conductor wire 411 has the conductor portion contact surface 412, a conductor portion top surface 413, and two conductor portion side surfaces 414 in the case of viewing a cross section in a direction orthogonal to the extending direction thereof. The conductor portion contact surface 412 is a surface that faces the substrate 20 through the adhesive portion 30 and is in contact with the adhesive portion 30. The conductor portion contact surface 412 has an uneven shape. In one or more embodiments of the invention, a part of the conductive particle 416 protrudes from the elastomer 417 on the conductor portion contact surface 412, whereby the conductor portion contact surface 412 has an uneven shape. The uneven shape of the conductor portion contact surface 412 is based on surface roughness of the conductor portion contact surface 412. Note that, a form of the conductor portion contact surface 412 is not particularly limited to the above description.

The conductor portion top surface 413 is a surface located on an opposite side from the conductor portion contact surface 412 in the conductor wire 411. This conductor portion top surface 413 includes a linear top surface flat portion 4131. In one or more embodiments of the invention, the elastomer 417 enters between conductive particles 416 on the conductor portion top surface 413. For this reason, on the conductor portion top surface 413, the linear top surface flat portion 4131 is formed by exposed portions of slightly scattered conductive particles 416 and the elastomer 417 covering the conductive particles 416. Note that, a form of the top surface flat portion 4131 of the conductor portion top surface 413 is not particularly limited to the above description.

The top surface flat portion 4131 is a portion in which a part of half or more of a width of the conductor portion top surface 413 is continuously linear. In one or more embodiments of the invention, the top surface flat portion 4131 is formed on the entire conductor portion top surface 413. A flatness of the top surface flat portion 4131 is 0.5 μm or less. Note that, the flatness can be defined by JIS (JIS B0621 (1984)).

The flatness of the top surface flat portion 4131 is obtained using a non-contact measuring method using laser light. Specifically, the flatness is measured by irradiating a measurement target (here, the conductor portion top surface 413) with band-like laser light and imaging reflected light on an imaging element (for example, two-dimensional CMOS). A method (maximum deviation type flatness) of setting planes passing through three points as far as possible, respectively, in a plane of the target and calculating a maximum value of deviations thereof as the flatness is used as a method of calculating the flatness. Note that, the measuring method and the calculating method of the flatness are not particularly limited to the above description. For example, the measuring method of the flatness may be a contact type measuring method using a dial gauge, etc. A method (maximum inclination type flatness) of calculating a value of a gap generated when the target plane is interposed between parallel planes as the flatness may be used as the calculating method of the flatness.

Each of the conductor portion side surfaces 414 is interposed between the conductor portion contact surface 412 and the conductor portion top surface 413. The conductor portion side surface 414 is connected to the conductor portion contact surface 412 at one end 4141 and is connected to the conductor portion top surface 413 at the other end 4142. The conductor portion side surface 414 and a side surface of the adhesive portion 30 are continuously connected to each other. In one or more embodiments of the invention, two conductor portion side surfaces 414 and 414 of one conductor wire 411 are inclined to approach a center of the conductor wire 411 as being away from the substrate 20. In this case, the conductor wire 411 has a tapered shape a width of which is narrower as being away from the substrate 20 in the cross section width direction.

The conductor portion side surface 414 includes a linear side surface flat portion 4143. In one or more embodiments of the invention, the elastomer 417 enters between the conductive particles 416 on the conductor portion side surface 414. For this reason, on the conductor portion side surface 414, the linear side surface flat portion 4143 is formed by exposed portions of slightly scattered conductive particles 416 and the elastomer 417 covering the conductive particles 416. Note that, a form of the side surface flat portion 4143 of the conductor portion side surface 414 is not particularly limited to the above description. Incidentally, since the conductive particles 416 are covered with the elastomer 417 on the conductor portion side surface 414, electric insulation between adjacent wiring portions 41 is improved, and occurrence of migration can be suppressed.

The side surface flat portion 4143 is a portion in which a part of half or more of a width of the conductor portion side surface 414 is continuously linear. In one or more embodiments of the invention, the side surface flat portion 4143 is formed on the entire conductor portion side surface 414. A flatness of the side surface flat portion 4143 is 0.5 μm or more. The flatness of the side surface flat portion 4143 can be measured by the same method as that of measurement of the flatness of the top surface flat portion 4131 described above.

The conductor portion side surface 414 of one or more embodiments of the invention is a linear inclined surface inclined to approach the center of the conductor wire 411 as being away from the substrate 20. However, it is not particularly limited thereto. For example, the conductor portion side surface 414 may be a curved surface formed in an arc shape protruding outward. In this way, in a case in which the width of the conductor wire 411 increases as being away from the substrate 20, the conductor portion side surface 414 is present on an outer side of the conductor wire 411 from a fifth imaginary straight line L₅ passing through the both ends 4141 and 4142 thereof (that is, the conductor portion side surface 414 does not have a flared shape).

In one or more embodiments of the invention, from a viewpoint of suppressing occurrence of a locally disconnected state of the conductor wire 411 around the conductor portion top surface 413, an angle θ₂ between a fourth imaginary straight line L₄ extending along the main surface 21 of the substrate 20 and the fifth imaginary straight line L₅ is set to satisfy Expression (15) below.

90°≤θ₂≤120° (15)

From a viewpoint of firmly bringing the adhesive portion 30 and the conductor portion 40 into close contact with each other, a surface roughness of the conductor portion contact surface 412 is relatively larger than a surface roughness of the conductor portion top surface 413. Specifically, while the surface roughness Ra of the conductor portion contact surface 412 is 0.1 μm to 3 μm, the surface roughness Ra of the conductor portion top surface 413 is 0.001 μm to 1.0 μm. Note that, in one or more embodiments, the surface roughness Ra of the conductor portion contact surface 412 is 0.1 μm to 0.5 μm, and the surface roughness Ra of the conductor portion top surface 413 is 0.001 μm to 0.3 μm. A relationship of the surface roughness of the conductor portion top surface 413 with respect to the surface roughness of the conductor portion contact surface 412 is 0.01 to less than 1, or 0.1 to less than 1. Further, the surface roughness of the conductor portion top surface 413 is ⅕ or less of the width (maximum width) of the conductor wire 411. Note that, such surface roughness can be measured by the JIS method (JIS B0601 (revised Mar. 21, 2013)). Measurement of the surface roughness of the conductor portion contact surface 412 and the surface roughness of the conductor portion top surface 413 may be performed along the width direction of the conductor wire 411 or may be performed along the extending direction of the conductor wire 411.

Incidentally, as described in the JIS method (JIS B0601 (revised Mar. 21, 2013)), the “surface roughness Ra” here is “arithmetic average roughness Ra”. The “arithmetic average roughness Ra” is a roughness parameter obtained by cutting off a long wavelength component (waviness component) from a sectional curve. Separation of the waviness component from the sectional curve is performed on the basis of a measurement condition (for example, a size of the object, etc.) necessary for determining a shape.

In addition, similarly to the conductor portion top surface 413, the surface roughness of the conductor portion contact surface 412 is relatively larger than the surface roughness of the conductor portion side surface 414. While the surface roughness Ra of the conductor portion contact surface 412 is 0.1 μm to 3 μm, in one or more embodiments, the surface roughness Ra of the conductor portion side surface 414 is 0.001 μm to 1.0 μm, or 0.001 μm to 0.3 μm. Measurement of the surface roughness of the conductor portion side surface 414 may be performed along the width direction of the conductor wire 411 or may be performed along the extending direction of the conductor wire 411.

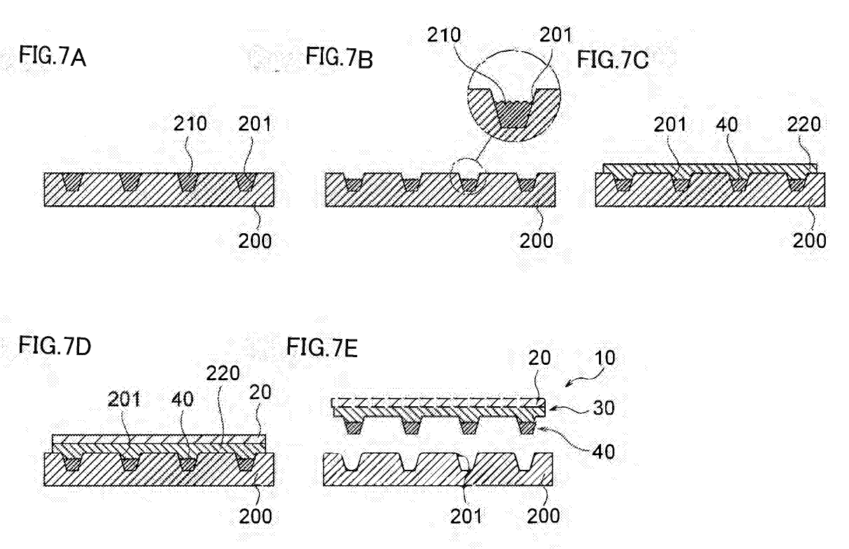

Next, a method of manufacturing the stretchable board 10 according to one or more embodiments of the invention will be described in detail with reference to FIG. 7A to FIG. 7E.

FIG. 7A to FIG. 7E are cross-sectional views illustrating the method of manufacturing the stretchable board according to one or more embodiments of the invention.

First, as illustrated in FIG. 7A, an intaglio 200 in which a concave portion 201 having a shape corresponding to the shape of the conductor portion 40 is formed is prepared.

Examples of a material of which the intaglio 200 is made may include nickel, silicon, glasses such as silicon dioxide, ceramics, organic silica, glassy carbon, thermoplastic resin, and photocurable resin. A width and a depth of the concave portion 201 are set according to the width and the height of the conductor portion 40 to be formed. In one or more embodiments of the invention, a cross-sectional shape of the concave portion 201 has a tapered shape that narrows toward a bottom. An inner wall surface of the concave portion 201 is a flat surface.

Note that, a release layer (not illustrated) made of a graphite-based material, a silicone-based material, a fluorine-based material, a ceramic-based material, an aluminum-based material, etc. are formed in advance on a surface of the concave portion 201 to improve a release property.

The concave portion 201 of the intaglio 200 is filled with a conductive material 210. A conductive paste obtained by mixing the conductive particles 416, the elastomer 417, water or a solvent, and various additives is used as such a conductive material 210. Examples of the solvent contained in the conductive paste may include α-terpineol, butyl carbitol acetate, butyl carbitol, 1-decanol, butyl cellosolve, diethylene glycol monoethyl ether acetate, and tetradecane.

Examples of a method of filling the concave portion 201 of the intaglio 200 with the conductive material 210 may include a dispensing method, an inkjet method, and a screen printing method. Alternatively, the examples may include a method of wiping off, scraping off, sucking up, pasting and taking off, washing away, or blowing away the conductive material applied to a part other than the concave portion 201 after coating using a slit coating method, a bar coating method, a blade coating method, a dip coating method, a spray coating method, or a spin coating method.

Subsequently, as illustrated in FIG. 7B, the conductor portion 40 is formed by heating the conductive material 210 filled in the concave portion 201 of the intaglio 200. A heating condition of the conductive material 210 can be appropriately set according to a composition of the conductive material, etc. By this heat treatment, the conductive material 210 shrinks in volume. In addition, a portion of the conductive material 210 not facing the concave portion 201 is formed in an uneven shape by being subjected to a heat treatment in a state exposed to the outside. On the other hand, a portion of the conductive material 210 facing the concave portion 201 is formed in a flat surface by transfer of the inner wall surface of the concave portion 201.

Note that, a method of treating the conductive material 210 is not limited to heating. It is possible to adopt irradiation with an energy ray such as an infrared ray, an ultraviolet ray or laser light or only drying. Alternatively, two or more of these treatment methods may be combined.

Subsequently, as illustrated in FIG. 7C, an object obtained by substantially uniformly applying an adhesive material 220 for forming the adhesive portion 30 onto the substrate 20 is prepared. The material contained in the above-mentioned adhesive portion 30 is used as such an adhesive material 220. Examples of a method for applying the adhesive material 220 onto the substrate 20 may include a screen printing method, a spray coating method, a bar coating method, a dipping method, and an ink jet method.

Subsequently, as illustrated in FIG. 7D, the substrate 20 and the adhesive material 220 are disposed on the intaglio 200 and the substrate 20 is pressed against the intaglio 200 so that the adhesive material 220 enters the concave portion 201 of the intaglio 200, and the adhesive material 220 is cured. Examples of a method of curing the adhesive material 220 may include irradiation with an energy ray such as an ultraviolet ray or infrared laser light, heating, heating and cooling, and drying. In this way, the adhesive portion 30 is formed. In addition, the substrate 20 and the conductor portion 40 are adhered to each other by the adhesive portion 30.

Note that, a method of forming the adhesive portion 30 is not particularly limited to the above description. For example, after applying the adhesive material 220 onto the intaglio 200 (the intaglio 200 in a state illustrated in FIG. 7B) on which the conductor portion 40 is formed and disposing the substrate 20 on the adhesive material 220, the adhesive material 220 may be cured in a state in which the substrate 20 is disposed on the intaglio 200 and pressed, thereby forming the adhesive portion 30.

Subsequently, as illustrated in FIG. 7E, the substrate 20, the adhesive portion 30, and the conductor portion 40 are released from the intaglio 200. In this way, the stretchable board 10 can be obtained.

The stretchable board 10 of one or more embodiments of the invention has the following effects.

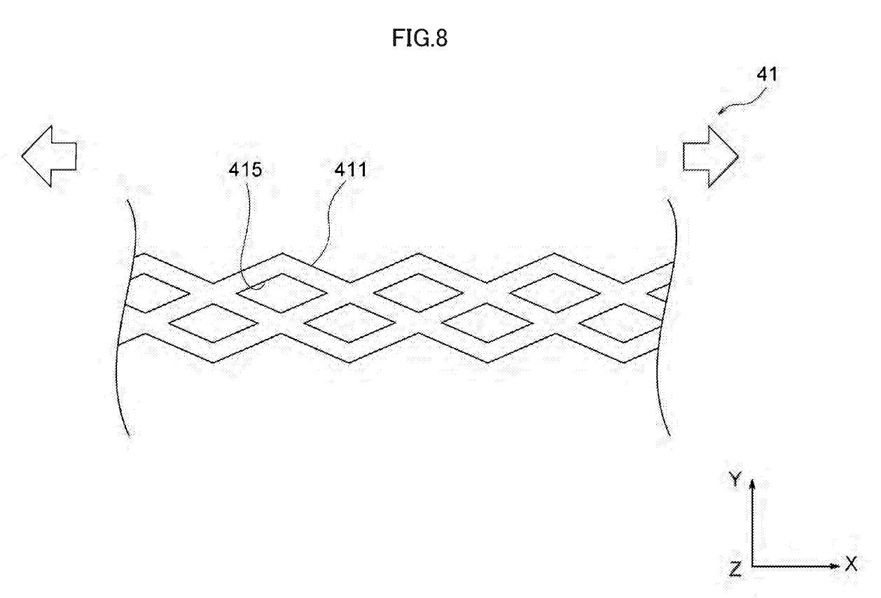

FIG. 8 is a plan view for description of an operation of the stretchable board according to one or more embodiments of the invention.

In the wiring portion 41 of one or more embodiments of the invention, the plurality of conductor wires 411 intersect with each other, and the openings 415 are formed by the plurality of conductor wires 411. In this case, as illustrated in FIG. 8, since the openings 415 can be deformed with respect to stretching of the wiring portion 41, stress applied to the wiring portion 41 is alleviated, and disconnection of the wiring portion 41 is unlikely to occur. For this reason, even when the wiring portion 41 stretches, an electric resistance value of the wiring portion 41 hardly changes. As a result, it is possible to improve durability of the stretchable board 10 against stretching.

In one or more embodiments of the invention, in plan view, the first imaginary straight line L₁ extending in the direction orthogonal to the extending direction of the wiring portion 41 intersects with at least two or more conductor wires 411. For this reason, even when a crack or isolation is caused and breakage occurs in some of the conductor wires 411 due to stretching of the wiring portion 41, a conduction path in the entire wiring portion 41 is not lost since the other conductor wires 411 other than some of the conductor wires 411 in which the breakage, etc. occurs are present. In addition, since the plurality of conductor wires 411 is present in the extending direction of the wiring portion 41, even when some of the conductor wires 411 break, an increase in the electric resistance value of the entire wiring portion 41 is suppressed. In this way, even when the wiring portion 41 stretches, the electric resistance value of the wiring portion 41 hardly changes. As a result, it is possible to improve durability of the stretchable board 10 against stretching.

In one or more embodiments of the invention, the wiring portion 41 includes the plurality of openings 415 mutually having the same shape, and the plurality of openings 415 is repeatedly arranged along the extending direction of the wiring portion 41. For this reason, since stress due to the stretching of the wiring portion 41 is uniformly applied to the entire wiring portion 41, local cracking and peeling of the conductor wire hardly occurs. In this way, even when the wiring portion 41 stretches, the electric resistance value of the wiring portion 41 hardly changes. As a result, it is possible to improve durability of the stretchable board 10 against stretching.

In one or more embodiments of the invention, the conductor wire 411 extends to be inclined with respect to the extending direction of the wiring portion 41. For this reason, when the stretchable board 10 stretches in the extending direction of the wiring portion 41, in comparison with a case in which the conductor wire is extended in the direction parallel or perpendicular to the extending direction of the wiring portion, it is possible to suppress an increase in the electric resistance value of the entire wiring portion 41 while suppressing deterioration of the stretching property of the wiring portion 41. In particular, in a case in which the angle θ₁ is set to satisfy the above Expression (8), the above effects can be more remarkably obtained. In a case in which the angle θ₁ is set to satisfy the above Expression (9), the above effects can be even more remarkably obtained.

In one or more embodiments of the invention, the wiring portion 41 is set to satisfy at least one of the above Expressions (10) and (11) and satisfy the above Expression (13). In this case, when at least one of the above Expressions (10) and (11) is satisfied, it is possible to suppress cracking and peeling from easily occurring in the conductor wire 411 due to the excessively small width W₁ of the conductor wire 411 while suppressing deterioration of the stretching property of the stretchable board 10 due to the excessively large width W₁ of the conductor wire 411. In addition, when the above Expression (13) is satisfied, it is possible to suppress cracking and peeling from easily occurring in the conductor wire 411 due to the excessively large pitch P₁ and stress concentration by stretching while suppressing deterioration of the stretching property of the stretchable board 10 due to the excessively small pitch P₁ between the adjacent conductor wires 411.

In one or more embodiments of the invention, since the conductor wire 411 contains the conductive material having the stretching property, the conductor wire 411 can be deformed, so that the stress applied to the wiring portion 41 is alleviated, and disconnection of the wiring portion 41 is unlikely to occur. For this reason, even when the wiring portion 41 stretches, the electric resistance value of the wiring portion 41 hardly changes. As a result, it is possible to improve durability of the stretchable board 10 against stretching.

In one or more embodiments of the invention, the surface roughness Ra of the conductor portion contact surface 412 of the conductor wire 411 is set to be relatively larger than the surface roughness Ra of the conductor portion top surface 413 and the conductor portion side surface 414. For this reason, the conductor portion 40 and the adhesive portion 30 are firmly adhered to each other, and it is possible to suppress falling of the conductor portion 40 from the substrate 20. In addition, in a case in which the stretchable board 10 is stretched, peeling of an interface between the conductor portion 40 and the adhesive portion 30 can be suppressed. In this way, mechanical strength of the stretchable board 10 can be improved.

In one or more embodiments of the invention, the conductor wire 411 is set to satisfy the above Expression (15). For this reason, it is possible to suppress a case in which the width of the conductor portion top surface 413 of the conductor wire 411 is excessively small, the conductive particle 416 is not present around the conductor portion top surface 413, and thus a part around the conductor portion top surface 413 does not contribute to conduction of the wiring portion 41.

In one or more embodiments, the “stretchable board 10” corresponds to an example of a “stretchable board” in the invention, the “substrate 20” corresponds to an example of a “substrate” in the invention, the “wiring portion 41” corresponds to an example of a “conductor portion” in the invention, the “conductor wire 411” corresponds to an example of a “conductor wire”, the “opening 415” corresponds to an example of an “opening” in the invention, the “conductive particle 416” corresponds to an example of a “conductive particle” in the invention, the “elastomer 417” corresponds to an example of an “elastomer” in the invention, the “conductor portion contact surface 412” corresponds to an example of a “first surface” in the invention, the “conductor portion top surface 413” corresponds to an example of a “second surface” in the invention, the “conductor portion side surface 414” corresponds to an example of a “third surface” in the invention, the “main surface 21” corresponds to an example of a “main surface” of the substrate in the invention, the “first imaginary straight line L₁” corresponds to an example of a “first imaginary straight line” in the invention, the “second imaginary straight line L₂” corresponds to an example of a “second imaginary straight line” in the invention, the “third imaginary straight line L₃” corresponds to an example of a “third imaginary straight line” in the invention, the “fourth imaginary straight line L₄” corresponds to an example of a “fourth imaginary straight line” in the invention, and the “fifth imaginary straight line L₅” corresponds to an example of a “fifth imaginary straight line” in the invention.

Embodiments heretofore explained are described to facilitate understanding of the present invention and are not described to limit the present invention. It is therefore intended that the elements disclosed in the above embodiments include all design changes and equivalents to fall within the technical scope of the present invention.

For example, a cover lay (not illustrated) for protecting the conductor portion 40 may be further provided on the stretchable board 10 described in the above embodiments. Such a cover lay is formed to cover the conductor portion 40 except for the terminal portion 42 of the conductor portion 40. As a material of which such a cover lay is made, it is possible to use the same material as the material of which the substrate 20 is made or the same material as that of the elastomer 417.

For example, the conductor portion 40 may be made of a conductive material not having the stretching property. For example, the conductor portion may be made of copper wiring. Alternatively, it is possible to use a non-stretchable conductive paste.

In a case in which the conductor portion 40 contains the conductive material having the stretching property, the invention is not limited to a case in which the conductive particle 416 and the elastomer 417 are contained as in the above embodiments. For example, a conductive polymer such as polyacetylene may be used. Alternatively, instead of the conductive particle, a material in which a fibrous substance such as a silver nanowire or a carbon nanotube is contained in an elastomer may be used.

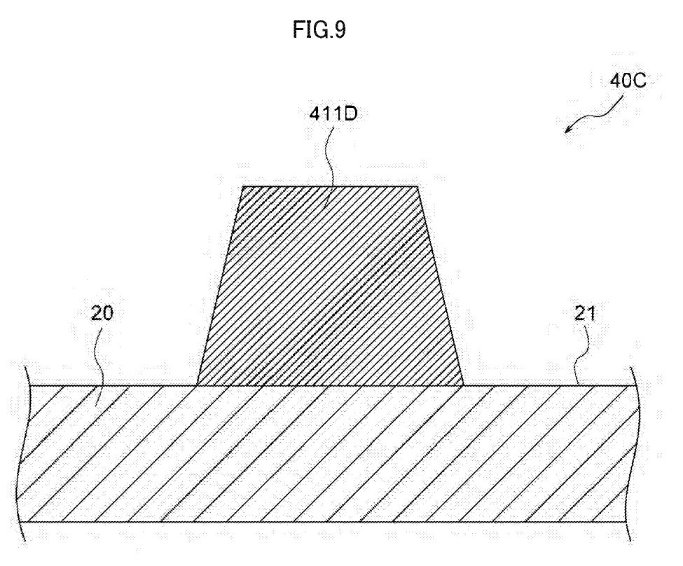

In the above embodiments, the adhesive portion 30 is interposed between the substrate 20 and the conductor portion 40. However, the invention is not particularly limited thereto. FIG. 9 is a cross-sectional view illustrating a stretchable board according to one or more embodiments of the invention. In a stretchable board 10C illustrated in FIG. 9, a conductor portion 40C (conductor wire 411D) is directly formed on a main surface 21 of a substrate 20. Such a conductor portion 40C is formed by printing a conductive paste similar to the above-described conductive paste on the substrate 20 using a screen printing method, a dispensing method, an intaglio printing method, a letterpress printing method, an offset printing method, etc., and then curing the conductive paste through a curing treatment such as heating or electromagnetic wave irradiation.

In the above embodiments, the stretchable board 10 is used for electrically connecting the external circuits 100 to each other. However, it is not particularly limited to the above description. For example, although not particularly illustrated, the stretchable board may be a stretchable board including an electronic device such as an IC device or a thin film transistor (TFT) and a conductor portion on the same substrate. In this case, the conductor portion may be formed to electrically connect electric components mounted on the same substrate to each other.

### EXAMPLES

Hereinafter, the invention will be described more specifically using Examples and Comparative Examples. The following Examples and Comparative Examples are used to verify durability of the stretchable board in the above-described embodiments.

### Example 1

In Example 1, a silver paste (XA9424, manufactured by Fujikura Kasei Co., Ltd.) made of an elastomer and a conductive particle was prepared. Then, an intaglio was filled with a conductive paste and heated under a condition of about 150° C. and 60 minutes, and the conductive paste was cured, thereby forming a conductor portion. The conductor portion was formed to mutually cross a plurality of conductor wires with each other and include a plurality of openings mutually having the same shape by these conductor wires. With regard to this conductor portion, a width W₂ of the conductor portion, a width W₁ and a thickness H of the conductor wires, a pitch P₁ between adjacent conductor wires, the number of intersection points of an imaginary straight line extending in a width direction of the conductor portion and the conductor wires (hereinafter also referred to as “a minimum number of conduction paths”), and an angle θ₁ between an imaginary straight line along an extending direction of the conductor portion and an imaginary straight line along an extending direction of the conductor wires were set as shown in Table 1. Then, an adhesive material made of an elastomer (TB3164D manufactured by ThreeBond Co., Ltd.) was applied onto the intaglio, and a substrate (SR1 manufactured by Fujikura Rubber Ltd.) made of an elastomer having width 1.5 mm×length 80 mm×thickness 0.1 mm was pressed against the intaglio while the adhesive material was interposed therebetween. In this state, an ultraviolet ray was irradiated under a condition of 3,000 mJ, and the adhesive material was cured, thereby forming an adhesive portion having a thickness of 10 inn. Thereafter, the substrate, the conductor portion, and the adhesive portion were released from the intaglio to obtain a test sample. The following test was conducted using the test sample.

<<Stretching Endurance Test>>

The test sample was stretched at a speed of 30 mm/min at room temperature while holding both longitudinal ends of the test sample at a holding interval of 50 mm. In this case, an electric resistance value between holding portions at both longitudinal ends of the conductor portion was measured, and an elongation rate of the test sample when the electric resistance value became twice of an initial electric resistance of the test sample was measured. A result is shown in Table 1 as a ratio with respect to a measured value in Comparative Example 1 described below.

### Examples 2 to 6

In Examples 2 to 6, test samples were manufactured similarly to the test sample according to Example 1 except that a width W₂ of a conductor portion, a width W₁ and a thickness H of conductor wires, a pitch P₁ between adjacent conductor wires, a minimum number of conduction paths, and an angle θ₁ between an imaginary straight line along an extending direction of the conductor portion and an imaginary straight line along an extending direction of the conductor wires were set as shown in Table 1.

With regard to these test samples, a stretching endurance tests were conducted similarly to Example 1. Results are shown in Table 1 as a ratio with respect to the measured value in Comparative Example 1 described below.

### Comparative Example 1

In Comparative Example 1, a test sample was manufactured similarly to the test sample according to Example 1 except that a conductor portion was shaped in the form of a solid pattern having width 1,000 μm×thickness 40 μm was formed.

With regard to this test sample, a stretching endurance test was conducted similarly to Example 1. A result is shown in Table 1 as a reference value.

In addition, a test below was conducted using the test samples according to Examples 3 to 6 and Comparative Example 1.

<<Repeated Endurance Test>>

Both longitudinal ends of each of the test samples was held such that a holding interval corresponds to 50 mm, and the test sample was repeatedly stretched at 10% relative to a total length of the test sample at a speed of 500 mm/min at a rate of 30 times/min at room temperature. In this case, an electric resistance value between holding portions at both longitudinal ends of the conductor portion was measured, and the number of times of repeated stretching of the test sample when the electric resistance value became twice of an initial electric resistance of the test sample was measured. Results are shown in Table 1 as ratios with respect to the measured value in Comparative Example 1.

TABLE 1

| | | | | | Minimum | | | | | | |
|---|---|---|---|---|---|---|---|---|---|---|---|
| | | | | | number of | | | | | | |
| | Width | Width | Pitch | Thickness | conduction | | | | | Elongation | Repeated |
| | W₂ | W₁ | P₁ | H | paths | Angle θ₁ | | | | rate | stretching |
| | [μm] | [μm] | [μm] | [μm] | [number] | [degree] | W₁/W₂ | P₁/W₂ | H/W₁ | [times] | [times] |
| Example 1 | 1000 | 10 | 50 | 40 | 13 | 45 | 0.01 | 5 | 4 | 1.8 | |
| Example 2 | 1000 | 10 | 100 | 40 | 6 | 45 | 0.01 | 10 | 4 | 2.2 | |
| Example 3 | 1000 | 50 | 100 | 40 | 7 | 45 | 0.05 | 2 | 0.8 | 1.2 | 2.6 |
| Example 4 | 1000 | 50 | 250 | 40 | 3 | 45 | 0.05 | 5 | 0.8 | 2.0 | 37.1 |
| Example 5 | 1000 | 50 | 500 | 40 | 1 | 45 | 0.05 | 10 | 0.8 | 2.1 | 12.1 |
| Example 6 | 1000 | 100 | 500 | 40 | 1 | 45 | 0.1 | 5 | 0.4 | 1.8 | 21.5 |
| Comparative | 1000 | — | — | 40 | — | — | — | — | — | 1.0 | 1.0 |
| Example 1 | | | | | | | | | | | |

### Evaluation of Examples 1 to 6 and Comparative Example 1

As shown in Table 1, in Examples 1 to 6 in which the conductor portion was formed to mutually cross the plurality of conductor wires with each other and include the plurality of openings by these conductor wires, in comparison with Comparative Example 1 in which the conductor portion was shaped in the form of the solid pattern, it is possible to confirm that a high elongation rate is obtained and the electric resistance value of the conductor portion hardly changes even when the conductor portion is stretched.

In particular, it is possible to confirm that the electric resistance value of the conductor portion hardly changes even when the conductor portion is stretched by setting a ratio (W₁/W₂) of the width W₁ to the width W₂ to satisfy the above Expression (11), setting a ratio (P₁/W₁) of the pitch P₁ to the width W₁ to satisfy the above Expression (13), and setting a ratio (H/W₁) of the thickness H to the width W₁ to satisfy the above Expression (14).

That is, from the results of Examples 1 to 6, it is possible to confirm that, even when the conductor portion stretches, the electric resistance value of the conductor portion hardly changes, and improvement of durability of the stretchable board with respect to stretching can be appropriately realized by forming the conductor portion to mutually cross the plurality of conductor wires with each other and include the plurality of openings by these conductor wires.

In addition, as shown in Table 1, in Examples 3 to 6 in which the conductor portion was formed to mutually cross the plurality of conductor wires with each other and include the plurality of openings by these conductor wires, in comparison with Comparative Example 1 in which the conductor portion was shaped in the form of the solid pattern, it is possible to confirm that the electric resistance value of the conductor portion hardly changes even when the conductor portion is repeatedly stretched.

In particular, from the results of Example 4 and Example 5, in a case in which the number of intersection points with the imaginary straight line orthogonal to the extending direction of the conductor portion is at least two or more (in a case in which the minimum number of conduction paths is two or more), it is possible to confirm that the electric resistance value of the conductor portion hardly changes even when the conductor portion is repeatedly stretched.

That is, from the results of Examples 3 to 6, it is possible to confirm that, even when the conductor portion is repeatedly stretched, the electric resistance value of the conductor portion hardly changes, and improvement of durability of the stretchable board with respect to repeated stretching can be appropriately realized by forming the conductor portion to mutually cross the plurality of conductor wires with each other and include the plurality of openings by these conductor wires.

### Examples 7 to 12

In Examples 7 to 12, a width W₂ of a conductor portion, a width W₁ and a thickness H of conductor wires, a pitch P₁ between adjacent conductor wires, a minimum number of conduction paths, and an angle θ₁ were set as shown in Table 2 to manufacture test samples similarly to the test sample according to Example 1.

With regard to the test samples according to Examples 7 to 12, the above-described stretching endurance tests were conducted. Results are shown in Table 2 as ratios with respect to a measured value in Comparative Example 2 described below. Note that, in the stretching endurance test, in a case in which a measured value of an elongation rate of a test sample according to an example is larger than 6.45 times a measured value of an elongation rate of a test sample according to Comparative Example 2, the value is greater than or equal to a measurement limit, and thus a result is set to above 6.45.

In addition, with regard to the test samples according to Examples 7 to 10, the above-described repeated stretching endurance tests were conducted. Results are shown in Table 2 as ratios with respect to a measured value in Comparative Example 2 described below. Note that, in the repeated stretching endurance test, when a measured value of the number of times of repeated stretching of a test sample according to an example is larger than 125 times a measured value of the number of times of repeated stretching of a test sample according to Comparative Example 2, the value is greater than or equal to a measurement limit, and thus a result is set to above 125.

### Comparative Example 2

In Comparative Example 2, a test sample was manufactured similarly to the test sample according to Comparative Example 1.

With regard to this test sample, the stretching endurance test and the repeated endurance test described above were conducted. Results are shown in Table 2 as reference values.

Note that, a condition of a curing treatment of a conductive paste is mutually the same between the test samples according to Examples 7 to 12 and Comparative Example 2. However, a condition of a curing treatment of a conductive paste is different from the test samples according to Examples 1 to 6 and Comparative Example 1 described above. For this reason, between Example 4 and Example 8, even though a width W₂ of a conductor portion, a width W₁ and a thickness H of conductor wires, a pitch P₁ between adjacent conductor wires, a minimum number of conduction paths, and an angle θ₁ were the same values, results of the stretching endurance test and the repeated endurance test were different values.

TABLE 2

| | | | | | Minimum | | | | | | |
|---|---|---|---|---|---|---|---|---|---|---|---|
| | | | | | number of | | | | | | |
| | Width | Width | Pitch | Thickness | conduction | | | | | Elongation | Repeated |
| | W₂ | W₁ | P₁ | H | paths | Angle θ₁ | | | | rate | stretching |
| | [μm] | [μm] | [μm] | [μm] | [number] | [degree] | W₁/W₂ | P₁/W₂ | H/W₁ | [times] | [times] |
| Example 7 | 1000 | 50 | 300 | 40 | 3 | 30 | 0.05 | 6 | 0.8 | 0.9 | 2.3 |
| Example 8 | 1000 | 50 | 250 | 40 | 3 | 45 | 0.05 | 5 | 0.8 | 2.4 | >125 |
| Example 9 | 1000 | 50 | 300 | 40 | 2 | 60 | 0.05 | 6 | 0.8 | 5.4 | >125 |
| Example 10 | 1000 | 50 | 500 | 40 | 1 | 75 | 0.05 | 10 | 0.8 | >6.45 | >125 |
| Example 11 | 1000 | 50 | 250 | 10 | 3 | 45 | 0.05 | 5 | 0.2 | | 6.5 |
| Example 12 | 1000 | 50 | 250 | 20 | 3 | 45 | 0.05 | 5 | 0.4 | | 10.9 |
| Comparative | 1000 | — | — | 40 | — | — | — | — | — | 1.0 | 1.0 |
| Example 2 | | | | | | | | | | | |

### Evaluation of Examples 7 to 12 and Comparative Example 2

As shown in Table 2, in Examples 7 to 10 in which the angle θ₁ is set to satisfy the above Expression (8), in comparison with Comparative Example 2 in which the conductor portion was shaped in the form of the solid pattern, it is possible to confirm that the electric resistance value of the conductor portion hardly changes even when the conductor portion is repeatedly stretched.

In particular, from the results of Examples 8 to 10, in a case in which the angle θ₁ is set to satisfy the above Expression (9), in comparison with Comparative Example 2, a high elongation rate is obtained and it is possible to confirm that the electric resistance value of the conductor portion hardly changes even when the conductor portion is stretched. In addition, from the results of Examples 8 to 10, in a case in which the angle θ₁ is set to satisfy the above Expression (9), in comparison with Comparative Example 2, it is possible to confirm that the electric resistance value of the conductor portion extremely hardly changes even when the conductor portion is repeatedly stretched.

That is, from the results of Examples 7 to 10, it is possible to confirm that improvement of durability of the stretchable board with respect to stretching and improvement of durability of the stretchable board with respect to repeated stretching can be appropriately realized by setting the angle θ1 to satisfy the above Expression (8) or the above Expression (9).

In addition, as shown in Table 2, in Examples 11 and 12 in which the ratio (H/W₁) of the thickness H to the width W₁ of the conductor portion is set to satisfy the above Expression (14), in comparison with Comparative Example 2, it is possible to confirm that the electric resistance value of the conductor portion hardly changes even when the conductor portion is repeatedly stretched.

That is, from the results of Examples 11 and 12, it is possible to confirm that improvement of durability of the stretchable board with respect to repeated stretching can be appropriately realized by setting the ratio (H/W₁) of the thickness H to the width W₁ of the conductor portion to satisfy the above Expression (14).

Although the disclosure has been described with respect to only a limited number of embodiments, those skill in the art, having benefit of this disclosure, will appreciate that various other embodiments may be devised without departing from the scope of the present invention. Accordingly, the scope of the invention should be limited only by the attached claims.

### REFERENCE SIGNS LIST

10 STRETCHABLE BOARD
20 SUBSTRATE
21 MAIN SURFACE
30 ADHESIVE PORTION
31 FLAT PORTION
311 UPPER SURFACE
32 PROTRUDING PORTION
321 ADHESIVE PORTION CONTACT SURFACE
40 CONDUCTOR PORTION
41 WIRING PORTION
411 CONDUCTOR WIRE
412 CONDUCTOR PORTION CONTACT SURFACE
413 CONDUCTOR PORTION TOP SURFACE
4131 TOP SURFACE FLAT PORTION
414 CONDUCTOR PORTION SIDE SURFACE
4141, 4142 END
4143 SIDE SURFACE FLAT PORTION
415 OPENING
416 CONDUCTIVE PARTICLE
417 ELASTOMER
42 TERMINAL PORTION
100 EXTERNAL CIRCUIT
200 INTAGLIO
201 CONCAVE PORTION
210 CONDUCTIVE MATERIAL
220 ADHESIVE MATERIAL

1. A stretchable board comprising:
a substrate having a stretching property; and
a conductor portion disposed on the substrate, wherein
the conductor portion comprises:
conductor wires intersecting with each other; and
an opening surrounded by the conductor wires.

2. The stretchable board according to claim 1, wherein
a first imaginary straight line extending in a direction orthogonal to an extending direction of the conductor portion intersects with at least two of the conductor wires.

3. The stretchable board according to claim 1, wherein
the conductor portion comprises a plurality of openings having the same shape and are repeatedly arranged along an extending direction of the conductor portion.

4. The stretchable board according to claim 1, wherein
at least one of Expression (1) and Expression (2) below is satisfied, and Expression (3) below is satisfied:
W₁≤100 μm (1)
W₁/W₂≤0.1 (2)
2≤P₁/W₁≤10 (3)
where, with respect to each of the conductor wires, W₁ denotes a width of the conductor wire, W₂ denotes a width of the conductor portion, and P₁ denotes a pitch between adjacent conductor wires.

5. The stretchable board according to claim 1, wherein
Expression (4) below is satisfied:
0.2≤H/W₁≤4 (4)
where, with respect to each of the conductor wires, W₁ denotes a width of the conductor wire and H denotes a height of the conductor wire.

6. The stretchable board according to claim 1, wherein
each of the conductor wires is inclined with respect to an extending direction of the conductor portion.

7. The stretchable board according to claim 6, wherein
Expression (5) below is satisfied:
30°≤θ₁<90° (5)
where θ₁ denotes an angle between a second imaginary straight line along an extending direction of the conductor portion and a third imaginary straight line along an extending direction of each of the conductor wires.

8. The stretchable board according to claim 7, wherein
Expression (6) below is satisfied:
45°≤θ₁≤75° (6).

9. The stretchable board according to claim 1, wherein
each of the conductor wires contains a conductive material having a stretching property, and
the conductive material includes a conductive particle and an elastomer.

10. The stretchable board according to claim 1, wherein
each of the conductor wires has:
a first surface facing the substrate;
a second surface on an opposite side of the first surface; and
a third surface interposed between the first surface and the second surface,
a surface roughness of the first surface is higher than a surface roughness of the second surface, and
the surface roughness of the first surface is higher than a surface roughness of the third surface.

11. The stretchable board according to claim 10, wherein
the substrate includes a linear main surface, and
Expression (7) below is satisfied:
90°≤θ₂≤120° (7)
where θ₂ denotes an angle between a fourth imaginary straight line along the linear main surface and a fifth imaginary straight line along the third surface.
